(19) United States
(12) Patent Application Publication
(10) Pub. No.: US 2024/0055557 A1
(43) Pub. Date: Feb. 15, 2024

(54) EPITAXIAL STRUCTURE

(71) Applicant: PlayNitride Display Co., Ltd., MiaoLi County (TW)

(72) Inventors: Yuan-Ting Fei, MiaoLi County (TW); Chi-Heng Chen, MiaoLi County (TW); Kuang-Yuan Hsu, MiaoLi County (TW)

(73) Assignee: PlayNitride Display Co., Ltd., MiaoLi County (TW)

(21) Appl. No.: 17/973,541

(22) Filed: Oct. 26, 2022

(30) Foreign Application Priority Data
Aug. 11, 2022 (TW) 111130157

(51) Int. Cl. H01L 33/12

(52) U.S. Cl. CPC H01L 33/12

(57) ABSTRACT

An epitaxial structure includes a first type semiconductor layer, a light emitting layer, a second type semiconductor layer, and a buffer layer structure. The light emitting layer is disposed on the first type semiconductor layer. The second type semiconductor layer is disposed on the light emitting layer. The buffer layer structure is disposed on one side of the first type semiconductor layer away from the second type semiconductor layer and includes a first buffer layer and a second buffer layer. The second buffer layer is located between the first buffer layer and the first type semiconductor layer, and the first buffer layer has a chlorine concentration greater than a chlorine concentration of the second buffer layer.

### CROSS-REFERENCE TO RELATED APPLICATION

This application claims the priority benefit of Taiwan application serial no. 111130157, filed on Aug. 11, 2022. The entirety of the above-mentioned patent application is hereby incorporated by reference herein and made a part of this specification.

### BACKGROUND

### Technical Field

The disclosure relates to an epitaxial structure, and more particularly, to an epitaxial structure having a light emitting layer and a buffer structure.

### Description of Related Art

In recent years, the possibility of application of micro light emitting diodes (micro LEDs) to active light emitting displays has been gradually explored. Compared with current mainstream light emitting diode (LED) backlight displays, active light emitting displays have made great progress in brightness, contrast, and color gamut. Moreover, from the perspective of LED chips, micro LEDs have the advantages of better energy efficiency and significantly longer lifespan than organic light emitting diodes (OLEDs).

Although the development of micro LEDs has gradually matured, there are still many technical problems to be overcome. For example, the electrostatic discharge (ESD) phenomenon commonly exists in electronic elements; in particular, micro LEDs are greatly reduced in volume compared with the conventional structure, which leads to a relatively increased chance of ESD caused by factors such as manufacturing process or operation application, and the risk of failure caused by ESD is also increased.

Therefore, how to improve the anti-electrostatic capability of micro LEDs to improve the proper rate of elements still has room for efforts at this stage.

### SUMMARY

The disclosure provides an epitaxial structure, which has good anti-electrostatic discharge capability.

According to an embodiment of the disclosure, the epitaxial structure includes a first type semiconductor layer, a light emitting layer, a second type semiconductor layer, and a buffer layer structure. The light emitting layer is disposed on the first type semiconductor layer. The second type semiconductor layer is disposed on the light emitting layer. The buffer layer structure is disposed on one side of the first type semiconductor layer away from the second type semiconductor layer and includes a first buffer layer and a second buffer layer. The second buffer layer is located between the first buffer layer and the first type semiconductor layer, and the first buffer layer has a chlorine concentration greater than a chlorine concentration of the second buffer layer.

In order to make the aforementioned features and advantages of the disclosure comprehensible, embodiments accompanied with drawings are described in detail as follows.

### BRIEF DESCRIPTION OF THE DRAWINGS

FIGS. 1 to 4 are schematic cross-sectional views of epitaxial structures according to some embodiments of the disclosure, respectively.

FIGS. 5A to 5C are various concentration-thickness relationship diagrams of the first buffer layer in the epitaxial structure, respectively.

### DESCRIPTION OF THE EMBODIMENTS

In the following embodiments, terms used to indicate directions, such as “up,” “down,” “front,” “back,” “left,” and “right,” merely refer to directions in the accompanying drawings. Therefore, the directional terms used are regarded as illustrative rather than restrictive of the disclosure.

In the accompanying drawings, the drawings illustrate the general features of the methods, structures, or materials used in the particular embodiments. However, the drawings shall not be interpreted as defining or limiting the scope or nature covered by the embodiments. For example, the relative size, thickness, and location of film layers, regions, or structures may be reduced or enlarged for clarity.

In the following embodiments, the same or similar elements will be designated by the same or similar reference numerals, and descriptions thereof will be omitted. In addition, the features of different embodiments may be combined with each other when they are not in conflict, and simple equivalent changes and modifications made according to the specification or the claims are still within the scope of the disclosure.

The terms such as “first” and “second” mentioned in the specification or the claims are only used to name different elements or to distinguish different embodiments or scopes and are not intended to limit the upper or lower limit of the number of the elements, nor are they intended to limit the manufacturing order or disposition order of the elements. Furthermore, the disposition of an element/film layer on (or over) another element/film layer may encompass the situation where the element/film layer is disposed directly on (or over) the other element/film layer, and the two elements/film layers are in contact with each other; and the situation where the element/film layer is indirectly disposed on (or over) the other element/film layer, and one or more elements/film layers exist between the two elements/film layers.

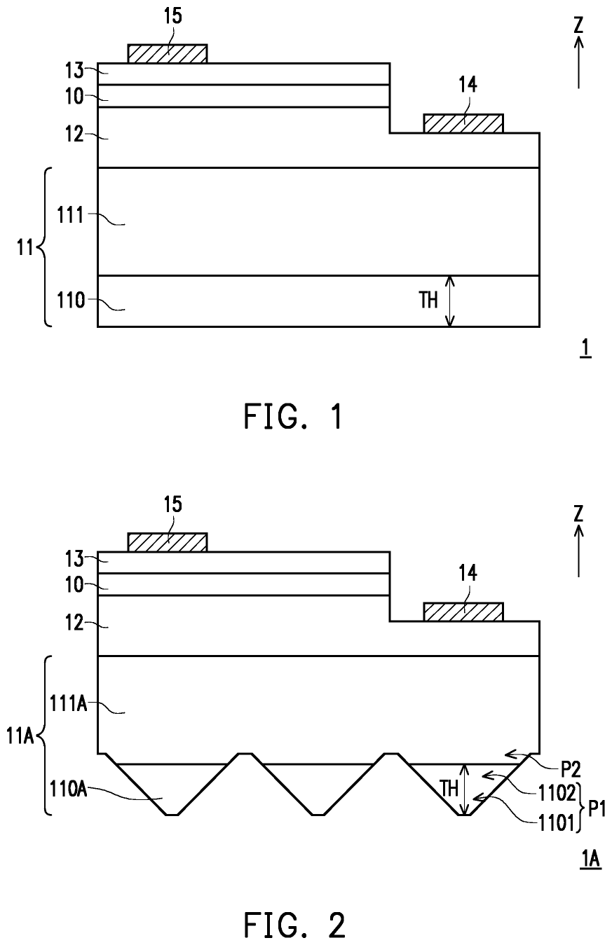

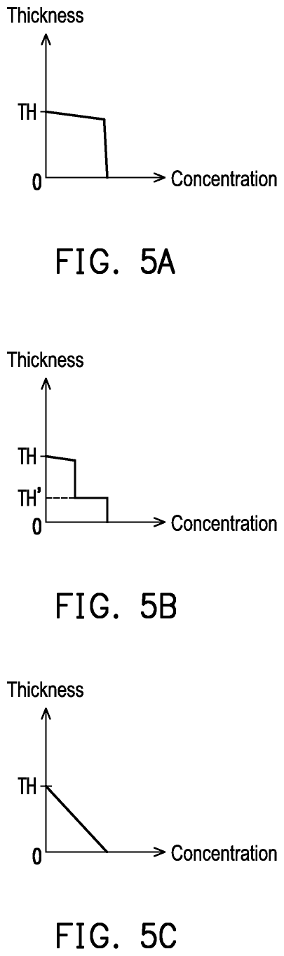

FIGS. 1 to 4 are schematic cross-sectional views of epitaxial structures according to some embodiments of the disclosure, respectively. FIGS. 5A to 5C are various concentration-thickness relationship diagrams of the first buffer layer in the epitaxial structure, respectively.

Referring to FIG. 1, an epitaxial structure 1 may be a micro light emitting diode (LED) chip and includes a first type semiconductor layer 12, a second type semiconductor layer 13, and a light emitting layer 10 disposed between the first type semiconductor layer 12 and the second type semiconductor layer 13. The epitaxial structure 1 further includes a buffer layer structure 11 disposed on one side of the first type semiconductor layer 12 away from the second type semiconductor layer 13. According to different design requirements, the epitaxial structure 1 may further include other elements. For example, a first electrode 14 and a second electrode 15 may be additionally disposed on the epitaxial structure 1, but not limited thereto. For example, the epitaxial structure 1 may be epitaxial film layers on an epitaxial wafer and may include the above-mentioned various layer structures of the micro LED chip.

In some embodiments, although not shown, the epitaxial structure 1 may optionally include a substrate, and the above-mentioned elements and film layers may be formed on the substrate. The material of the substrate may include sapphire, gallium nitride, gallium arsenide, silicon, silicon germanium, glass, ceramic, silicon carbide, aluminum nitride, or other suitable materials. Alternatively, after the above-mentioned elements and film layers are formed on the substrate, the substrate may be optionally removed, for example, the substrate can be separated from the buffer layer structure 11 thereon by a laser lift-off (LLO) process.

The buffer layer structure 11 may include a first buffer layer 110 and a second buffer layer 111. The first buffer layer 110 and the second buffer layer 111 may be sequentially formed on the substrate, so that the second buffer layer 111 is located between the first buffer layer 110 and the first type semiconductor layer 12. Materials of the first buffer layer 110 and the second buffer layer 111 may include III-V materials, such as nitrides and their alloys (e.g., gallium nitride, aluminum nitride, indium nitride, indium gallium nitride, aluminum gallium nitride, aluminum indium gallium nitride, etc.), arsenide and its alloys (e.g., gallium arsenide, aluminum arsenide, indium arsenide, indium gallium arsenide, aluminum gallium arsenide, aluminum indium gallium arsenide, etc.), phosphides and their alloys (e.g., gallium phosphide, aluminum phosphide, indium phosphide, indium gallium phosphide, aluminum gallium phosphide, aluminum indium gallium phosphide, etc.), but are not limited thereto. In some embodiments, the first buffer layer 110 and the second buffer layer 111 may be optionally doped with dopants such as magnesium, silicon, carbon, gallium, indium, or nitrogen, but are not limited thereto.

The first buffer layer 110 has a chlorine concentration greater than a chlorine concentration of the second buffer layer 111, so as to improve the anti-electrostatic discharge capability of the epitaxial structure 1. Specifically, the buffer layer structure 11 (e.g., the first buffer layer 110 relatively far away from the light emitting layer 10) contains chlorine, which may improve the voltage pulse that the epitaxial structure 1 can withstand, and the anti-electrostatic discharge capability of the epitaxial structure 1 has a positive correlation with the chlorine concentration of the buffer layer structure 11. Therefore, the anti-electrostatic discharge capability of the epitaxial structure 1 may be improved by increasing the chlorine concentration of the buffer layer structure 11, especially the chlorine concentration of the first buffer layer 110.

For example, the chlorine concentration of the first buffer layer 110 may range between 10¹⁴ atom/cm³ and 10¹⁷ atom/cm³, that is, 10¹⁴ atom/cm³≤chlorine concentration≤10¹⁷ atom/cm³. When the chlorine concentration of the first buffer layer 110 ranges between 10¹⁴ atom/cm³ and 10¹⁵ atom/cm³, that is, when 10¹⁴ atom/cm³≤chlorine concentration≤10¹⁵ atom/cm³, the epitaxial structure 1 may have better electrical performance, for example, better anti-electrostatic discharge capability. The chlorine concentration of the first buffer layer 110 may be measured by a secondary ion mass spectrometer (SIMS), but not limited thereto.

It should be noted that, based on various options of the manufacturing process, existing forms of the “chlorine” referred to in the embodiments of the disclosure are not limited, including but not limited to chloride ions, chloride ion compounds, chlorine molecular compounds (such as binary chlorides or polychlorinated compounds) or chlorates.

In some embodiments, the chlorine concentration of the first buffer layer 110 is 1.5 times or more the chlorine concentration of the second buffer layer 111, for example, the chlorine concentration of the first buffer layer 110 may be 1.7*10¹⁴ atom/cm³. When the chlorine concentration of the first buffer layer 110 is more than three times the chlorine concentration of the second buffer layer 111, for example, 5*10¹⁴ atom/cm³ to 10¹⁵ atom/cm³, the epitaxial structure 1 may have better electrical performance, for example, better anti-electrostatic discharge capability.

In some embodiments, a thickness TH of the first buffer layer 110 (e.g., the maximum thickness of the first buffer layer 110 in a direction Z) ranges between 5 nm and 4000 nm, that is, 5 nm≤TH≤4000 nm. When the thickness TH of the first buffer layer 110 ranges between 5 nm and 2000 nm, that is, when 5 nm≤TH≤2000 nm, the epitaxial structure 1 may have better electrical performance, for example, better anti-electrostatic discharge capability. For example, the thickness TH of the first buffer layer 110 may range between 100 nm and 2000 nm or between 500 nm and 2000 nm, such as 900 nm, but is not limited thereto.

The first type semiconductor layer 12 is disposed between the second buffer layer 111 and the light emitting layer 10, and the light emitting layer 10 is disposed between the first type semiconductor layer 12 and the second type semiconductor layer 13. One of the first type semiconductor layer 12 and the second type semiconductor layer 13 may be a P type semiconductor layer, and the other one of the first type semiconductor layer 12 and the second type semiconductor layer 13 may be an N type semiconductor layer. Materials of the first type semiconductor layer 12 and the second type semiconductor layer 13 may include III-V materials, such as nitrides and their alloys (e.g., gallium nitride, aluminum nitride, indium nitride, indium gallium nitride, aluminum gallium nitride, aluminum indium gallium nitride, etc.), arsenide and its alloys (e.g., gallium arsenide, aluminum arsenide, indium arsenide, indium gallium arsenide, aluminum gallium arsenide, aluminum indium gallium arsenide, etc.), phosphides and their alloys (e.g., gallium phosphide, aluminum phosphide, indium phosphide, indium gallium phosphide, aluminum gallium phosphide, aluminum indium gallium phosphide, etc.), but are not limited thereto. The light emitting layer 10 may be a multiple quantum well (MQW) structure, but is not limited thereto.

The first electrode 14 is disposed on the first type semiconductor layer 12 and is electrically coupled to the first type semiconductor layer 12. The second electrode 15 is disposed on the second type semiconductor layer 13 and is electrically coupled to the second type semiconductor layer 13. Materials of the first electrode 14 and the second electrode 15 may include metals, alloys or combinations thereof, but are not limited thereto. In the embodiment, the first type semiconductor layer 12 is exposed by mesa etching to realize electrical coupling with the first electrode 14, but not limited thereto. For example, the first type semiconductor layer 12 may also be exposed by etching through the second type semiconductor layer 13 and the light emitting layer 10 through an open via, and the first electrode 14 is then connected to the first type semiconductor layer 12 through the via. In addition, the top surface of the first electrode 14 and the top surface of the second electrode 15 may also be flush with each other based on requirements (e.g., direct bonding), which is not limited by the disclosure.

In some embodiments, although not shown, the epitaxial structure 1 may further include a protective layer, and the protective layer covers at least the sidewalls of the light emitting layer 10 to provide the light emitting layer 10 with proper protection (e.g., blocking water and oxygen). The material of the protective layer may include silicon oxide, silicon nitride, silicon oxynitride or other suitable materials. The following embodiments may be changed in the same way, and will not be repeated below.

In some embodiments, although not shown in FIG. 1, the first buffer layer 110 may include multiple sub-layers disposed in an overlapping manner. For example, the first buffer layer 110 may include an intrinsic aluminum gallium nitride (i-AlGaN) layer and an intrinsic gallium nitride (i-GaN) layer, and the i-GaN layer is disposed between the i-AlGaN layer and the second buffer layer 111. In some embodiments, the thickness of the i-AlGaN layer is about 20 nm, and the i-AlGaN layer is vaporized and thinned or even disappears during the LLO process, but not limited thereto.

Referring to FIG. 2, the main differences between an epitaxial structure 1A and the epitaxial structure 1 of FIG. 1 are described as follows. In a buffer layer structure 1A of the epitaxial structure 1A, a first buffer layer 110A includes a patterned structure P1, and a second buffer layer 111A includes a patterned structure P2 connected to the patterned structure P1 of the first buffer layer 110A. In detail, when the buffer layer structure 11A is formed on a patterned sapphire substrate, the bottom of the buffer layer structure 11A forms a patterned structure complementary to a nano-pattern on the top surface of the sapphire substrate. In some embodiments, the thickness TH of the first buffer layer 110A is smaller than the depth of the nano-pattern on the top surface of the sapphire substrate, thereby forming the patterned structure P1 of the first buffer layer 110A and the patterned structure P2 of the second buffer layer 111A. The cross section of the patterned structure P1 is, for example, zigzag, but is not limited thereto. For example, the patterned structure P1 may also refer to a surface formed when the sapphire substrate is separated by LLO process, and the patterned structure P1 may also have a similar cross-sectional shape at this time. In the embodiment, the first buffer layer 110A may also be further divided into a tip region 1101 and other regions (e.g., a mesa region 1102), and most or all chlorine atoms are distributed in the tip region 1101, which may help improve the adverse effects of tip discharge due to charge accumulation on the patterned surface.

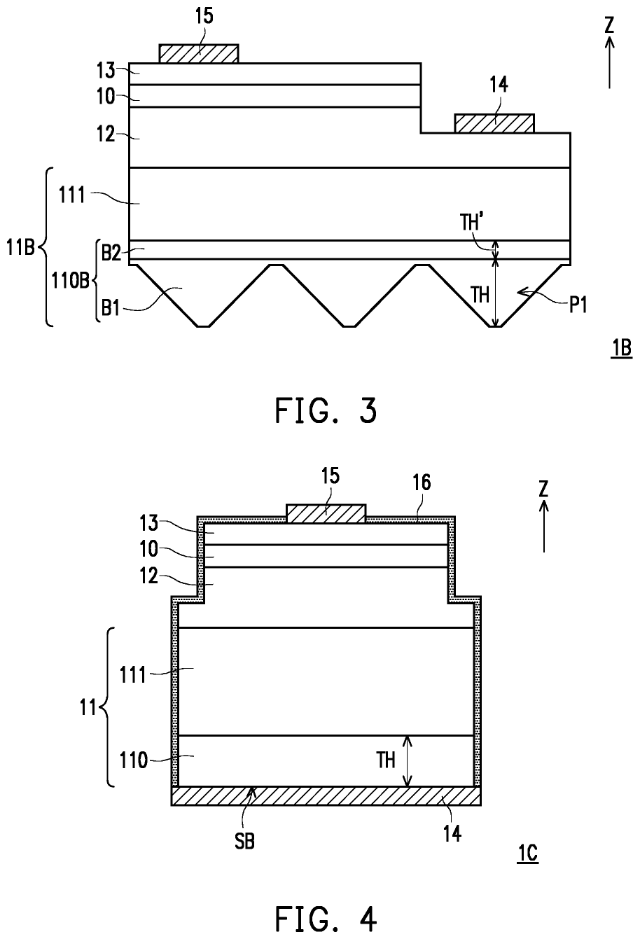

Referring to FIG. 3, the main differences between an epitaxial structure 1B and the epitaxial structure 1 of FIG. 1 are described as follows. In a buffer layer structure 11B of the epitaxial structure 1B, a first buffer layer 110B includes multiple sub-layers, such as a sub-layer B1 and a sub-layer B2, but the actual number of the sub-layers is not limited thereto. The difference from FIG. 2 is that the sub-layer B2 and the sub-layer B1 of the epitaxial structure 1B of FIG. 3 are of the same film structure (having the same molecular composition), while the first buffer layer 110A and the second buffer layer 111A of FIG. 2 belong to different film structures.

It should be noted that, in order to facilitate the understanding of the relevant features of the embodiment, the first buffer layer 110A in FIG. 2 and the first buffer layer 110B in FIG. 3 are enlarged and shown. Therefore, the size ratios of the first buffer layer 110A compared to the epitaxial structure 1A and the first buffer layer 110B compared to the epitaxial structure 1B are not shown according to the actual situation.

The sub-layer B1 may form the patterned structure P1 complementary to the nano-pattern on the top surface of the sapphire substrate, but is not limited thereto. In other embodiments, although not shown, the sub-layer B2 may include a patterned structure connected to the patterned structure P1 of the sub-layer B1. The chlorine concentration change of any one of the sub-layer B1 and the sub-layer B2 may decrease toward the direction close to the light emitting layer 10 (e.g., the direction Z). For details, please refer to the description of FIGS. 5A to 5C

Referring to FIG. 4, the main difference between an epitaxial structure 1C and the epitaxial structure 1 of FIG. 1 is that the epitaxial structure 1 of FIG. 1 is a horizontal micro LED chip, while the epitaxial structure 1C of FIG. 4 is a vertical micro LED chip. In detail, the first electrode 14 is disposed on a bottom surface SB of the first buffer layer 110, and the buffer layer structure 11 is located between the first electrode 14 and the first type semiconductor layer 12. The buffer layer structure 11 has the same type of dopant as the first type semiconductor layer 12, so that the first electrode 14 and the first type semiconductor layer 12 are electrically coupled. For example, when the first type semiconductor layer 12 is an N type semiconductor layer, the first buffer layer 110 and the second buffer layer 111 are both N type buffer layers. Conversely, when the first type semiconductor layer 12 is a P type semiconductor layer, both the first buffer layer 110 and the second buffer layer 111 are P type buffer layers.

The epitaxial structure 1C may further optionally include a protective layer 16. The protective layer 16 covers at least the sidewalls of the light emitting layer 10 to provide proper protection of the light emitting layer 10 (e.g., blocking water and oxygen). In some embodiments, as shown in FIG. 4, in addition to the sidewalls of the light emitting layer 10, the protective layer 16 may further cover the sidewalls of the buffer layer structure 11 and the sidewalls of the first type semiconductor layer 12, and extend from the sidewalls of the second type semiconductor layer 13 to the top surface of the second type semiconductor layer 13, but not limited thereto. The material of the protective layer 16 may include silicon oxide, silicon nitride, silicon oxynitride or other suitable materials.

In other embodiments, although not shown, the buffer layer structure 11 of the epitaxial structure 1C may also be changed to the buffer layer structure 11A shown in FIG. 2, and the first electrode 14 may be disposed on the patterned structure P1 of the first buffer layer 110A and the patterned structure P2 of the second buffer layer 111A by metal deposition. Besides, the first buffer layer 110A may also be implemented in a partial patterning manner to form a flat area (not shown) on a part of the surface of the patterned structure P1 for the disposition of the first electrode 14. Alternatively, although not shown, the buffer layer structure 11 of the epitaxial structure 1C may also be changed to the buffer layer structure 11B shown in FIG. 3, and the first electrode 14 may be disposed on the patterned structure P1 of the sub-layer B1.

In some embodiments, the chlorine concentration of the above-mentioned first buffer layer (such as the first buffer layer 110 of FIG. 1 or FIG. 4, the first buffer layer 110A of FIG. 2 or the first buffer layer 110B of FIG. 3) may be reduced toward a direction close to the light emitting layer 10 (e.g., the direction Z) in various forms. For example, as shown in FIG. 5A, the chlorine concentration of the first buffer layer may exhibit linear changes with different slopes as the thickness (i.e., the depth of the epitaxial structure) decreases. In detail, the chlorine concentration in the first buffer layer 110A may include linear variations in multiple stages. For example, on one side away from the first type semiconductor layer 12, the chlorine concentration of the first buffer layer 110A decreases linearly and slowly; on the other hand, in the top surface region on one side close to the first type semiconductor layer 12 (i.e., close to the thickness TH), the chlorine concentration of the first buffer layer 110A decreases rapidly, showing a linear steep drop. Alternatively, as shown in FIG. 5B, the chlorine concentration of the first buffer layer may decrease in a gradient. For example, the chlorine concentration of the first buffer layer may decrease steeply for the first time near a thickness TH′, and decrease steeply for the second time near the thickness TH. For example, in the embodiment of FIG. 3, the sub-layer B1 and the sub-layer B2 may have different chlorine concentrations and correspond to the thicknesses TH and TH′, respectively, and exhibit gradient changes as shown in FIG. 5B. It should be understood, however, that the section in which the chlorine concentration decreases in a gradient may be more than two times, and the chlorine concentration in each of the sections may not be a fixed value. Furthermore, as shown in FIG. 5C, the chlorine concentration of the first buffer layer may be linearly decreased to zero.

To sum up, in the embodiments of the disclosure, the anti-electrostatic discharge capability of the epitaxial structures may be improved by making the first buffer layer relatively far from the light emitting layer to contain chlorine.

Although the disclosure has been described with reference to the above embodiments, the described embodiments are not intended to limit the disclosure. People of ordinary skill in the art may make some changes and modifications without departing from the spirit and the scope of the disclosure. Thus, the scope of the disclosure shall be subject to those defined by the attached claims.

What is claimed is:

1. An epitaxial structure, comprising:
a first type semiconductor layer;
a light emitting layer disposed on the first type semiconductor layer;
a second type semiconductor layer disposed on the light emitting layer; and
a buffer layer structure disposed on one side of the first type semiconductor layer away from the second type semiconductor layer and comprising a first buffer layer and a second buffer layer, wherein the second buffer layer is located between the first buffer layer and the first type semiconductor layer, and the first buffer layer has a chlorine concentration greater than a chlorine concentration of the second buffer layer.

2. The epitaxial structure according to claim 1, wherein a thickness of the first buffer layer ranges between 5 nm and 4000 nm.

3. The epitaxial structure according to claim 1, wherein the chlorine concentration of the first buffer layer is 1.5 times or more the chlorine concentration of the second buffer layer.

4. The epitaxial structure according to claim 3, wherein the chlorine concentration of the first buffer layer ranges between 10¹⁴ atom/cm³ and 10¹⁷ atom/cm³.

5. The epitaxial structure according to claim 1, wherein the chlorine concentration of the first buffer layer decreases toward a direction close to the first type semiconductor layer.

6. The epitaxial structure according to claim 5, wherein the chlorine concentration of the first buffer layer has a linear change.

7. The epitaxial structure according to claim 6, wherein the chlorine concentration of the first buffer layer varies linearly in a plurality of stages, and the chlorine concentration of a region of the first buffer layer close to the first type semiconductor layer decreases faster than the chlorine concentration of a region of the first buffer layer far from the first type semiconductor layer.

8. The epitaxial structure according to claim 5, wherein the first buffer layer comprises a plurality of sub-layers disposed in an overlapping manner.

9. The epitaxial structure according to claim 8, wherein chlorine concentrations of the plurality of sub-layers are different.

10. The epitaxial structure according to claim 1, wherein the first buffer layer comprises a patterned structure.

11. The epitaxial structure according to claim 10, wherein the patterned structure of the first buffer layer comprises a tip region away from the first type semiconductor layer, and a chlorine concentration of the tip region is greater than chlorine concentrations of other regions of the first buffer layer.

12. The epitaxial structure according to claim 10, wherein the second buffer layer comprises another patterned structure connected to the patterned structure of the first buffer layer.
